(19) United States
(12) Patent Application Publication
(10) Pub. No.: US 2010/0279011 A1
(43) Pub. Date: Nov. 4, 2010

(54) NOVEL BISMUTH PRECURSORS FOR CVD/ALD OF THIN FILMS

(75) Inventors: Tianniu Chen, Rocky Hill, CT (US); Chongying Xu, New Milford, CT (US); Bryan C. Hendrix, Danbury, CT (US); William Hunks, Waterbury, CT (US); Thomas M. Cameron, Newtown, CT (US); Matthias Stender, Fox Point, WI (US); Gregory T. Stauf, New Milford, CT (US); Jeffrey F. Roeder, Brookfield, CT (US)

Correspondence Address: INTELLECTUAL PROPERTY / TECHNOLOGY LAW, PO BOX 14329, RESEARCH TRIANGLE PARK, NC, 27709, US

(73) Assignee: Advanced Technology Materials, Inc., Danbury, CT (US)

(21) Appl. No.: 12/740,992

(22) PCT Filed: Oct. 31, 2008
(86) PCT No.: PCT/US08/82134

§ 371 Date: Jul. 2, 2010

Related U.S. Application Data
(60) Provisional application No. 60/984,370, filed on Oct. 31, 2007.
(60) Provisional application No. 61/050,179, filed on May 2, 2008.

(51) Int. Cl. C23C 16/18; C07F 9/94; C07F 7/08; C09D 4/00

(52) U.S. Cl. 427/255.6; 556/64; 556/12; 106/287.18

(57) ABSTRACT

Bismuth precursors having utility for forming highly conformal bismuth-containing films by low temperature (<300° C.) vapor deposition processes such as CVD and ALD, including bismuth aminidates, bismuth guanidates, bismuth isoureates, bismuth carbamates and bismuth thiocarbamates, bismuth beta-diketonates, bismuth diketoiminates, bismuth diketiiminates, bismuth allyls, bismuth cyclopentadienyls, bismuth alkyls, bismuth alkoxides, and bismuth silyls with pendant ligands, bismuth silylamides, bismuth chelated amides, and bismuth ditelluroimidodiphosphinates. Also described are methods of making such precursors, and packaged forms of such precursors suitable for use in the manufacture of microelectronic device products. These bismuth precursors are usefully employed to form bismuth-containing films, such as films of GBT, Bi₂Te₃, Bi₄Ti₃O₁₂, SrBi₂Ta₂O₉, Bi—Ta—O, BiP and thermoelectric bismuth-containing films.

### CROSS-REFERENCE TO RELATED APPLICATIONS

The benefit of priority of U.S. Provisional Patent Application 60/984,370 filed Oct. 31, 2007 and U.S. Provisional Patent Application 61/050,179 filed May 2, 2008 is hereby claimed under the provisions of 35 USC 119. The disclosures of said U.S. Provisional Patent Application 60/984,370 and U.S. Provisional Patent Application 61/050,179 are hereby incorporated herein by reference, in their respective entireties, for all purposes.

### FIELD OF THE INVENTION

The present invention relates to precursors for use in depositing bismuth-containing films on substrates such as wafers or other microelectronic device substrates, as well as associated processes of making and using such precursors, and source packages of such precursors.

### DESCRIPTION OF THE RELATED ART

In the manufacture of microelectronic devices, there is emerging interest in the deposition of Ge₂Bi₂Te₅ (GBT) thin films for nonvolatile Phase Change Memory (PCM) such as phase change random access memory (PCRAM), due to the relative ease of integrating such films with silicon-based integrated circuits. CVD and ALD-like processing of these materials are of primary interest as deposition techniques for advanced device applications.

The anticipated use of high aspect ratio geometries in PCMs and the corresponding requirement to achieve smooth films of proper phase and non-segregated character, require processes that are efficient in forming high-quality bismuth-containing films at low temperatures.

While GBT(Ge₂Bi₂Te₅) films have recently been identified as potential candidates for such PCM applications, due to their faster phase transition times, there are a very limited number of bismuth CVD/ALD precursors available. Most of these available bismuth CVD/ALD precursors are alkyl- or aryl-based, such as trimethyl bismuth (Me₃Bi) and triphenyl bismuth (Ph₃Bi), and suffer from deficiencies such as high thermal stability accompanied by low reactivity that in turn require the use of high deposition temperatures. Such high temperatures in turn increase the potential for unwanted migration affects, side-reactions, carbon incorporation, and film defects. Other potential bismuth precursors suffer from deficiencies, such as high photosensitivity, low volatility, synthetic difficulties, and/or high delivery temperature requirements, which have limited their commercial viability.

In consequence, the art continues to seek new bismuth precursors having utility for vapor deposition processes to form bismuth-containing films in microelectronic device fabrication.

### SUMMARY OF THE INVENTION

The present invention relates to bismuth precursors useful in chemical vapor deposition and atomic layer deposition applications, to form corresponding bismuth-containing films on substrates, as well as associated processes and packaged forms of such precursors.

In one aspect, the invention relates to bismuth precursor selected from among:

(I) bismuth compounds of the formula:

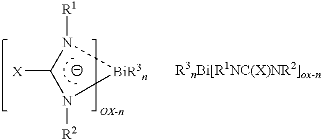

wherein:
X is selected from among H, C₁-C₆ alkyl, C₃-C₈ cycloalkyl, C₁-C₆ alkoxy, C₆-C₁₄ aryl, C₁-C₆ fluoroalkyl, C₃-C₁₈ alkylsilyl, silyl, amide, aminoalkyl, alkoxyalkyl, aryloxyalkyl, imidoalkyl, acetylalkyl and SiR₃ wherein each R is independently selected from branched and unbranched C₁-C₆ hydrocarbyl, e.g., alkyl;
each R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, amide, aminoalkyl, alkoxyalkyl, aryloxyalkyl, imidoalkyl, C₁-C₆ fluoroalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(II) bismuth compounds of the formula:

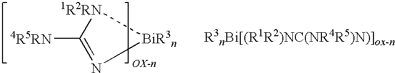

wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ, may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(III) bismuth compounds of the formula:

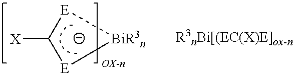

wherein:
E is either O or S;
X is selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
each R³ is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
   n is an integer having a value of from 0 to OX;
   (IV) bismuth compounds of the formulae:

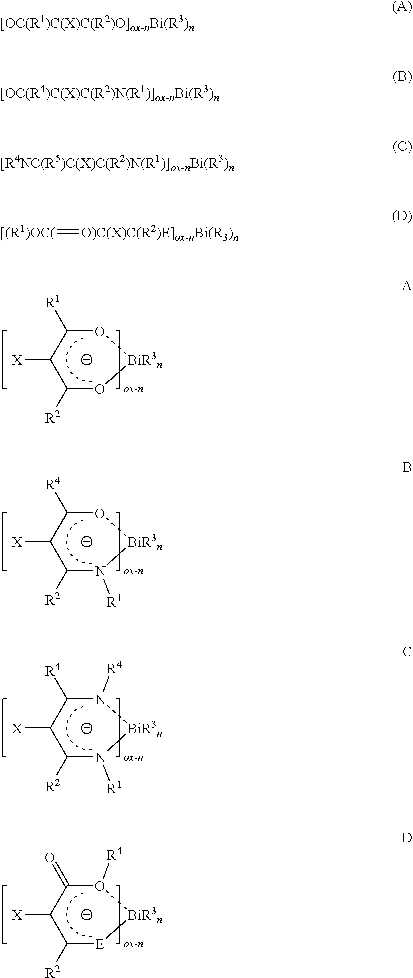

wherein:
X is selected from among C₁-C₆ alkyl, C₁-C₆ alkoxy, C₆-C₁₀ aryl, C₃-C₆ alkylsilyl, aminoalkyl, alkoxyalkyl, aryloxyalkyl, hydrogen, and acetylalkyl;
each R¹, R², R³, R⁴ and R⁵ may be the same as or different from the others, and each is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is oxygen or sulfur;
n is an integer having a value of from 0 to OX;
(V) bismuth compounds of the formulae:

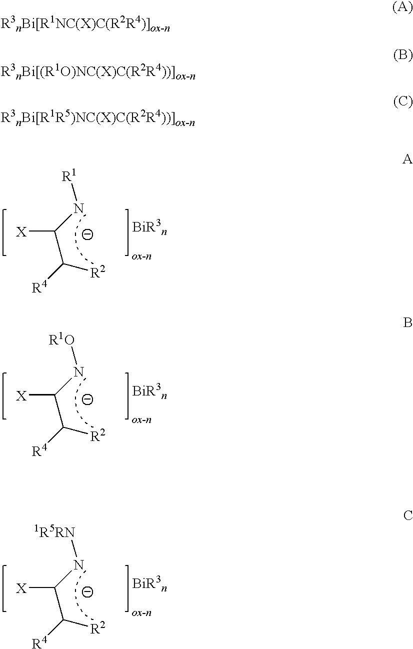

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each of R¹, R², R³, R⁴ and R⁵ may be the same as or different from the others and is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
each R³ is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
OX is the oxidation state of Bi (typically +3 or +5);
n is an integer having a value of from 0 to OX;
(VI) bismuth compounds of the formula:

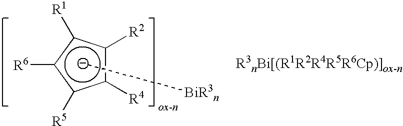

wherein:
Cp is cyclopentadienyl;
each of R¹, R², R³, R⁴, R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(VII) bismuth compounds of the formulae:

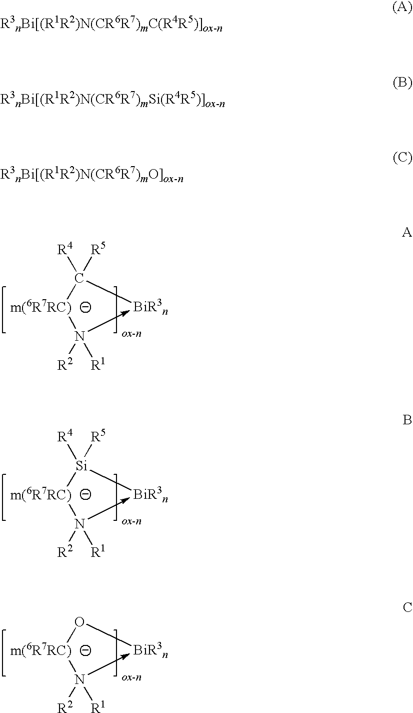

wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(VIII) bismuth compounds of the formulae:

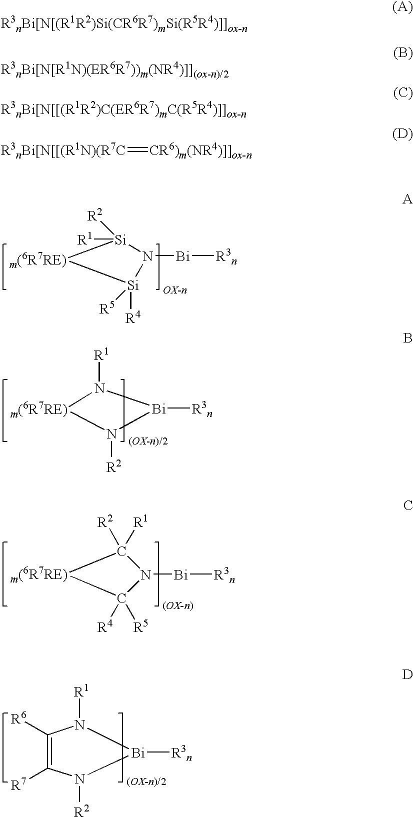

wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n is an integer having a value of from 0 to OX;
(IX) bismuth compounds of the formulae:

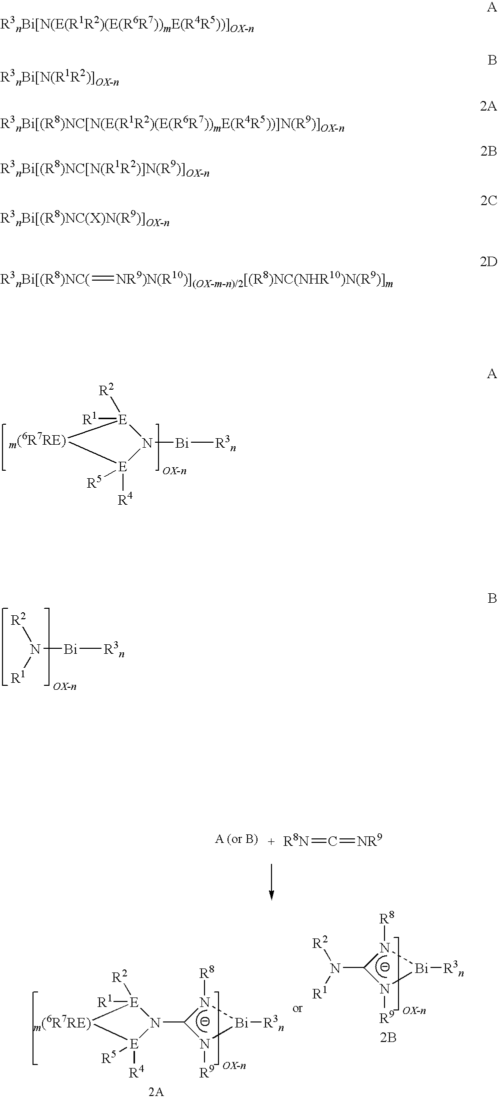

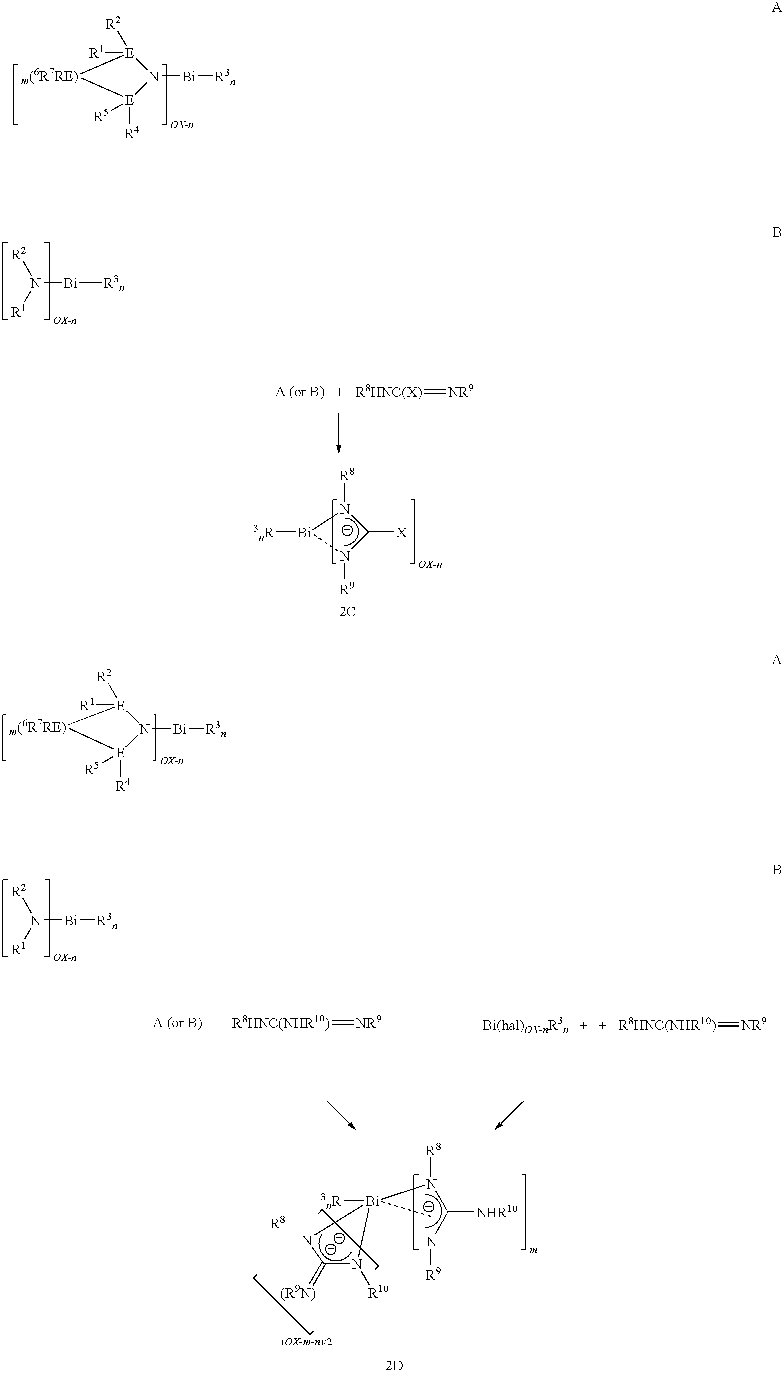

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX;
(X) bismuth compounds of the formula:

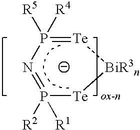

wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(XI) bismuth compounds of the formula:

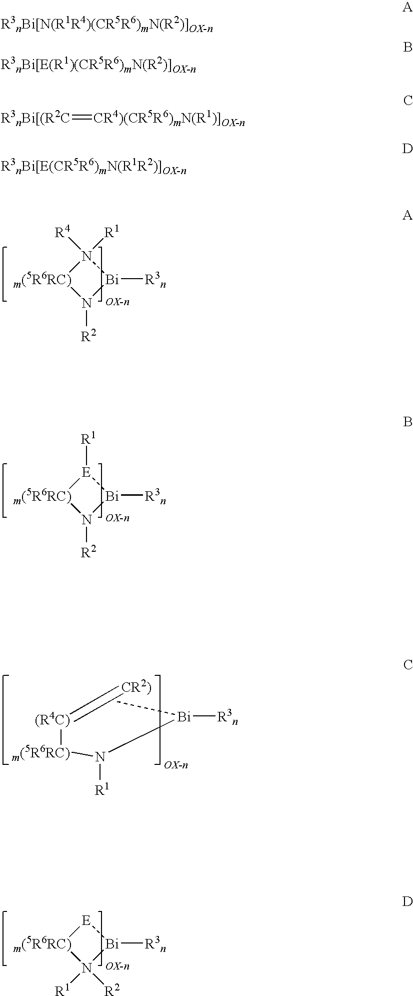

wherein:
each of R¹, R², R³, R⁴, R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n and m are each integers having a value of from 0 to OX;

### E is O or S.

(XII) bismuth compounds of the formula:

R³ₙBi(R¹)ₒₓ₋ₙ

wherein:
each of R¹ and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(XIII) bismuth compounds of the formula:

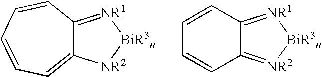

wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(XIV) bismuth compounds of the formula:

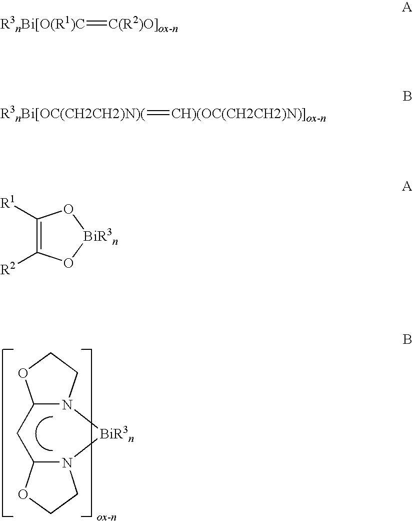

wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

In another aspect, the invention relates to a method of making a bismuth compound selected from among bismuth compounds of the formulae 2A, 2B, 2C and 2D,

R³ₙBi[(R⁸)NC[N(E(R¹R²)(E(R⁶R⁷))ₘE(R⁴R⁵))]N(R⁹)]_{OX-n} 2A

R³ₙBi[(R⁸)NC[N(R¹R²)]N(R⁹)]_{OX-n} 2B

R³ₙBi[(R⁸)NC(X)N(R⁹)]_{OX-n} 2C

R³ₙBi[(R⁸)NC(═NR⁹)N(R¹⁰)]_{(OX-m-n)/2}[(R⁸)NC(NHR¹⁰)N(R⁹)]ₘ 2D

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX;
such method comprising synthesizing the bismuth compound by a synthesis process including the following reaction scheme:

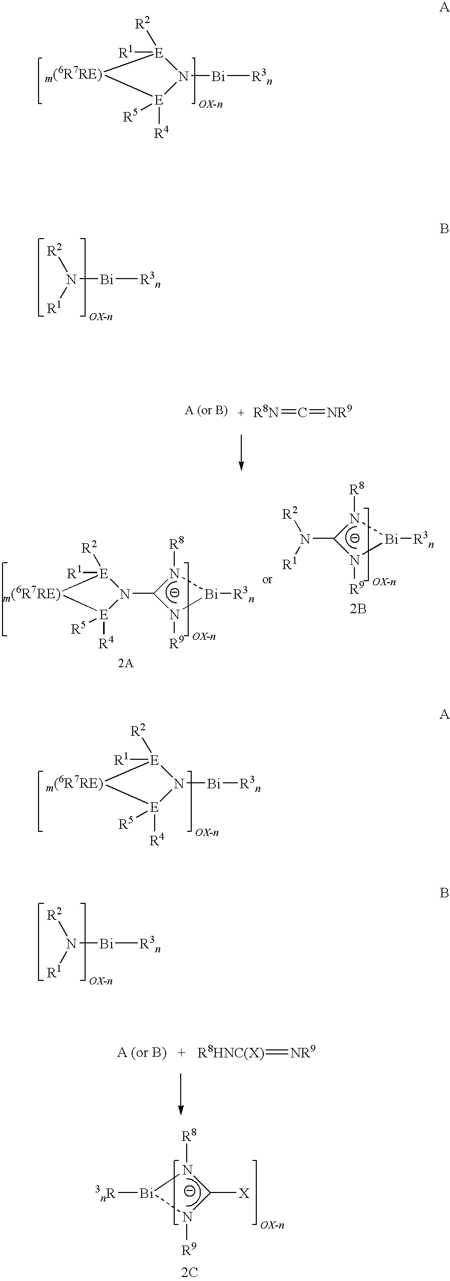

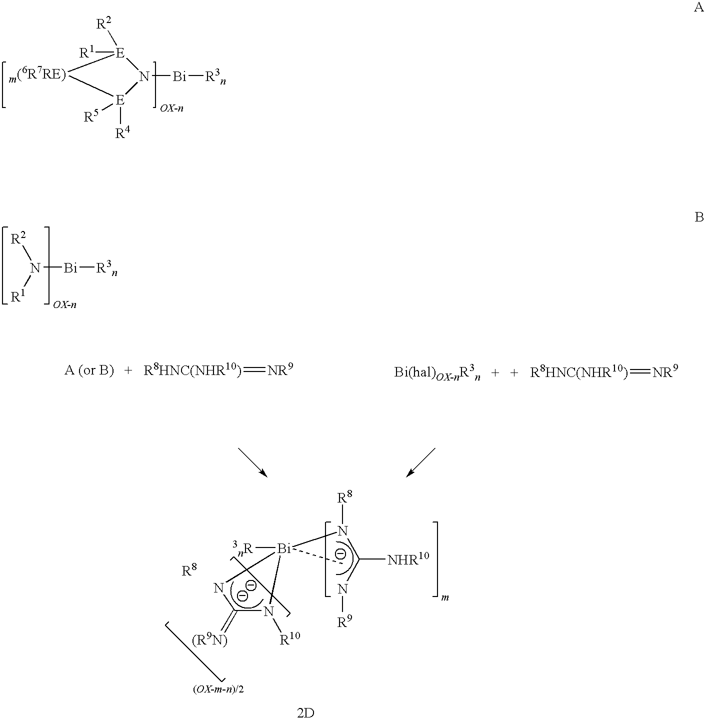

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX.

In a further aspect, the invention relates to a method of forming a bismuth-containing film on a substrate, said method comprising volatilizing a bismuth precursor of the invention, to form a precursor vapor, and contacting such precursor vapor with a substrate to form the bismuth-containing film thereon.

A further aspect of the invention relates to a precursor composition comprising at least one bismuth precursor of the invention, and a solvent for the bismuth precursor(s).

A still further aspect of the invention relates to a precursor vapor of a bismuth precursor of the invention.

An additional aspect of the invention relates to a precursor source package comprising a precursor storage and dispensing vessel containing a bismuth precursor of the invention.

In one aspect, the invention further relates to a method of combating pre-reaction of precursors described herein in a vapor deposition process for forming a film on a substrate, wherein the precursors described herein are susceptible to pre-reaction adversely affecting the film. In this aspect, the method involves introducing to the process a pre-reaction-combating agent selected from the group consisting of (i) heteroatom (O, N, S) organo Lewis base compounds, (ii) free radical inhibitors, and (iii) deuterium-containing reagents.

Another aspect of the invention relates to a method of combating pre-reaction of the precursors described in a vapor deposition process in which multiple feed streams are flowed to a deposition locus to form a film on a substrate, wherein at least one of said multiple feed streams includes a precursor susceptible to pre-reaction adversely affecting the film. The method involves introducing to at least one of said multiple feed streams or supplied materials therefor, or to the deposition locus, a pre-reaction-combating agent selected from the group consisting of (i) heteroatom (O, N, S) organo Lewis base compounds, (ii) free radical inhibitors, and (iii) deuterium-containing reagents.

A still further aspect of the invention relates to a composition, comprising a precursor as described herein and a pre-reaction-combating agent for said precursor, said pre-reaction-combating agent being selected from the group consisting of (i) heteroatom (O, N, S) organo Lewis base compounds, (ii) free radical inhibitors, and (iii) deuterium-containing reagents.

In a further aspect, the invention relates to a method of combating pre-reaction of a vapor phase precursor described herein in contact with a substrate for deposition of a film component thereon. The method involves contacting said substrate, prior to said contact of the vapor phase precursor therewith, with a pre-reaction-combating agent selected from the group consisting of (i) heteroatom (O, N, S) organo Lewis base compounds, (ii) free radical inhibitors, and (iii) deuterium-containing reagents.

In a further aspect, the invention relates to a process wherein the pre-reaction combating reagent is introduced to passivate the surface of a growing film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.). Such passivation/retardation followed by reactivation thus may be carried out in an alternating repetitive sequence, for as many repetitive cycles as desired, in ALD or ALD-like processes. Pre-reaction-combating agents can be selected from the group consisting of (i) heteroatom (O, N, S) organo Lewis base compounds, (ii) free radical inhibitors, and (iii) deuterium-containing reagents.

Another aspect of the invention relates to a vapor phase deposition process for forming a film on a substrate involving cyclic contacting of the substrate with at least one film precursor described herein that is undesirably pre-reactive in the vapor phase. The process involves introducing to said film during growth thereof a pre-reaction-combating reagent that is effective to passivate a surface of said film or to slow rate of deposition of said film precursor, and after introducing said pre-reaction-combating reagent, reactivating said film with a different film precursor.

Other aspects, features and embodiments of the invention will be more fully apparent from the ensuing disclosure and appended claims.

### BRIEF DESCRIPTION OF THE DRAWINGS

FIG. 1 is a schematic representation of a material storage and dispensing package containing a precursor of the present invention, in one embodiment thereof.

FIG. 2 is an nmr spectrum for Bi(Me-amd)₃.

FIG. 3 is an STA plot for Bi(Me-amd)₃.

FIG. 4 is an nmr spectrum for the product Bi[N(Bu^{t})(SiMe₃)]₃.

FIG. 5 is an STA plot for the product Bi[N(Bu^{t})(SiMe₃)].

### DETAILED DESCRIPTION OF THE INVENTION, AND PREFERRED EMBODIMENTS THEREOF

The present invention relates in various aspects to bismuth precursors having utility for forming highly conformal bismuth-containing films by low temperature (<300° C.) vapor deposition processes such as CVD and ALD, to methods of making such precursors, and to packaged forms of such precursors suitable for use in the manufacture of microelectronic device products.

The bismuth precursors of the invention are usefully employed in chemical vapor deposition and atomic layer deposition processes to form bismuth-containing films, such as films of GBT, Bi₂Te₃, Bi₄Ti₃O₁₂, SrBi₂Ta₂O₉, Bi—Ta—O, BiP and thermoelectric bismuth-containing films.

In general, the thicknesses of metal-containing layers in the practice of the present invention can be of any suitable value. In a specific embodiment of the invention, the thickness of the metal-containing layer can be in a range of from 5 nm to 500 nm or more.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer.

As used herein, the singular forms “a”, “and”, and “the” include plural referents unless the context clearly dictates otherwise.

As used herein, the identification of a carbon number range, e.g., in C₁-C₁₂ alkyl, is intended to include each of the component carbon number moieties within such range, so that each intervening carbon number and any other stated or intervening carbon number value in that stated range, is encompassed, it being further understood that sub-ranges of carbon number within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the invention. Accordingly, C₁-C₁₂ alkyl is intended to include methyl, ethyl, propyl, butyl, pentyl, hexyl, heptyl, octyl, nonyl, decyl, undecyl and dodecyl, including straight chain as well as branched groups of such types. It therefore is to be appreciated that identification of a carbon number range, e.g., C₁-C₁₂, as broadly applicable to a substituent moiety, enables, in specific embodiments of the invention, the carbon number range to be further restricted, as a sub-group of moieties having a carbon number range within the broader specification of the substituent moiety. By way of example, the carbon number range e.g., C₁-C₁₂ alkyl, may be more restrictively specified, in particular embodiments of the invention, to encompass sub-ranges such as C₁-C₄ alkyl, C₂-C₈ alkyl, C₂-C₄ alkyl, C₃-C₅ alkyl, or any other sub-range within the broad carbon number range.

The precursors of the invention may be further specified in specific embodiments by provisos or limitations excluding specific substituents, groups, moieties or structures, in relation to various specifications and exemplifications thereof set forth herein. Thus, the invention contemplates restrictively defined compositions, e.g., a composition wherein Rⁱ is C₁-C₁₂ alkyl, with the proviso that Rⁱ≠C₄ alkyl when R^{j} is silyl.

The precursors of the invention include various classes of bismuth compositions, encompassing bismuth amimidates, bismuth guanidates, bismuth isoureates, bismuth carbamates and bismuth thiocarbamates, bismuth beta-diketonates, bismuth diketoiminates, bismuth diketiiminates, bismuth allyls, bismuth cyclopentadienyls, bismuth alkyls, bismuth alkoxides, and bismuth silyls with pendant ligands, bismuth silylamides, bismuth chelate amides, bismuth guanidinates, and bismuth ditelluroimidodiphosphinates. Each of these classes is considered in turn below.

The bismuth amidinates, guanidinates and isoureates are species within the broad scope of bismuth compounds of the invention having the following formulae:

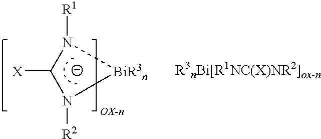

wherein:
X is selected from among H, C₁-C₆ alkyl, C₃-C₈ cycloalkyl, C₁-C₆ alkoxy, C₆-C₁₄ aryl, C₁-C₆ fluoroalkyl, C₃-C₁₈ alkylsilyl, silyl, amide, aminoalkyl, alkoxyalkyl, aryloxyalkyl, imidoalkyl, acetylalkyl and SiR₃ wherein each R is independently selected from branched and unbranched C₁-C₆ hydrocarbyl, e.g., alkyl;
each R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, amide, aminoalkyl, alkoxyalkyl, aryloxyalkyl, imidoalkyl, C₁-C₆ fluoroalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

The bismuth tetraalkylguanidates are species within the broad scope of bismuth compounds of the invention having the following formulae:

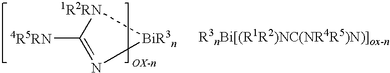

wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

The bismuth carbamates and thiocarbamates are species within the broad scope of bismuth compounds of the invention having the following formulae:

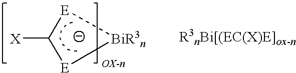

wherein:
E is either O or S;
X is selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
each R³ is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

The bismuth beta-diketonates, diketoiminates, and diketiiminates are species within the broad scope of bismuth compounds of the invention, having the following formulae:

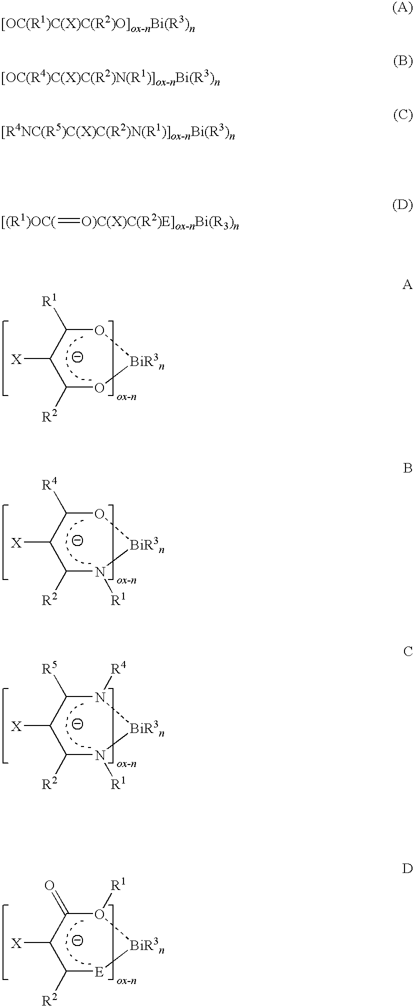

wherein:
X is selected from among C₁-C₆ alkyl, C₁-C₆ alkoxy, C₆-C₁₀ aryl, C₃-C₆ alkylsilyl, aminoalkyl, alkoxyalkyl, aryloxyalkyl, hydrogen, and acetylalkyl;
each R¹, R², R³, R⁴ and R⁵ may be the same as or different from the others, and each is independently selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, alkoxyalkyl, aryloxyalkyl, and acetylalkyl;
OX is the oxidation state of Bi (typically +3 or +5);
E is oxygen or sulfur;
n is an integer having a value of from 0 to OX.

The bismuth allyls are species within the broad scope of bismuth compounds of the invention having the following formulae:

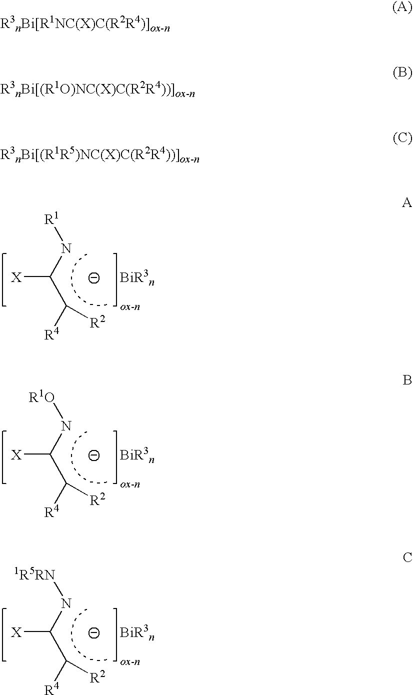

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each of R¹, R², R³, R⁴ and R⁵ may be the same as or different from the others and is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
each R³ is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
OX is the oxidation state of Bi (typically +3 or +5);
n is an integer having a value of from 0 to OX.

The bismuth cyclopentadienyls are species within the broad scope of bismuth compounds of the invention having the following formulae:

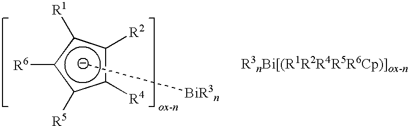

wherein:
Cp is cyclopentadienyl;
each of R¹, R², R³, R⁴, R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;

R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;

OX is the oxidation state of Bi (typically +3 or +5);
n is an integer having a value of from 0 to OX.

The bismuth alkyls, alkoxides and silyls with pendent ligands, are species within the broad scope of bismuth compounds of the invention having the following formulae:

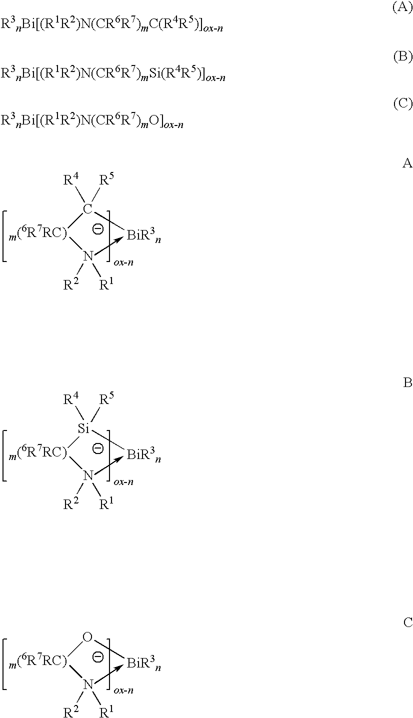

wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

The bismuth silylamides(cyclic) and chelate amides are species within the broad scope of bismuth compounds of the invention having the following formulae:

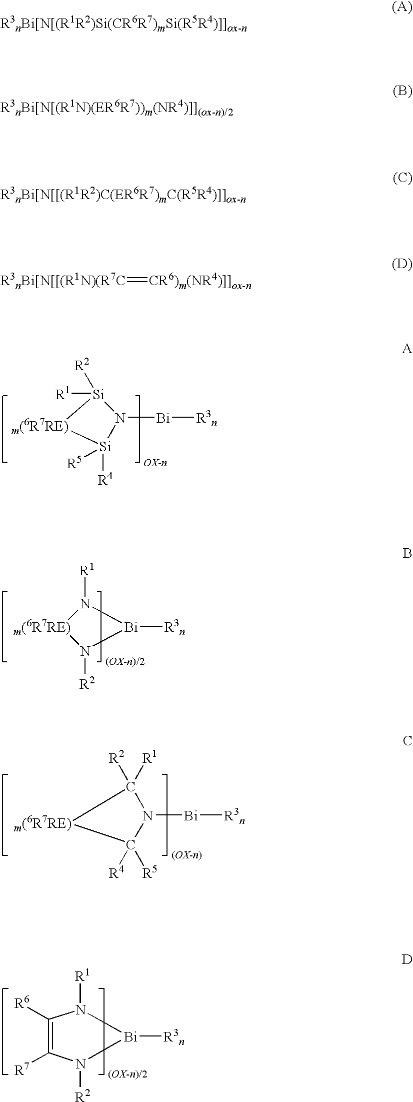

wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n is an integer having a value of from 0 to OX.

The bismuth guanidinates formed by carbodiimide insertion are species within the broad scope of bismuth compounds of the invention having the following formulae:

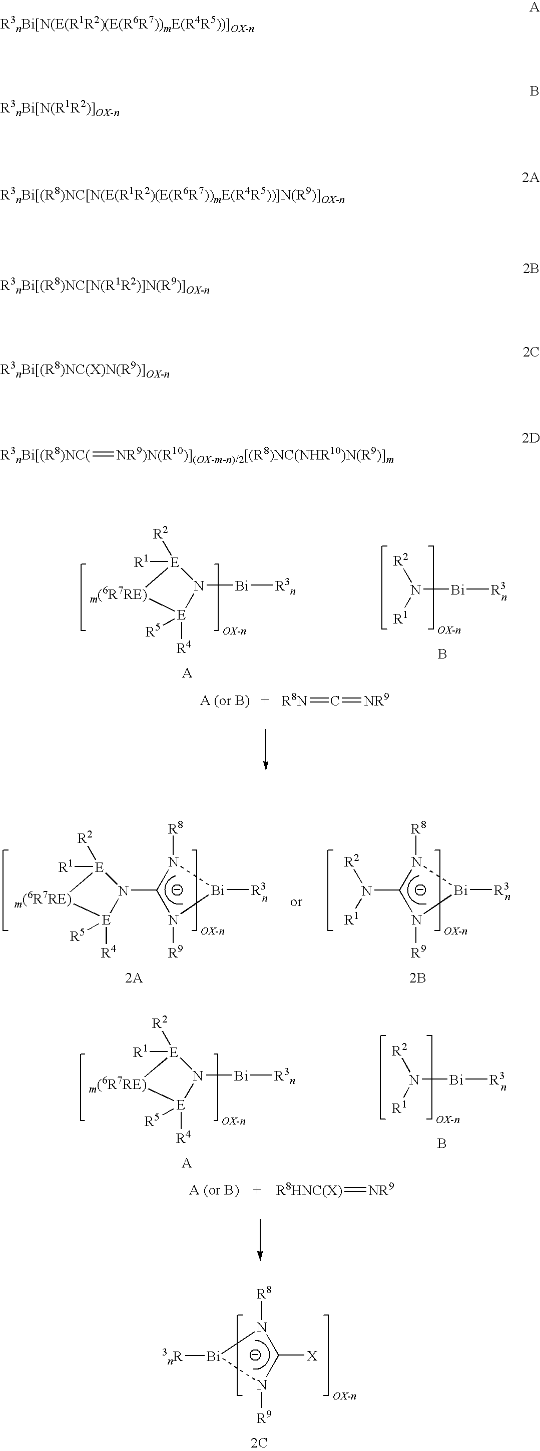

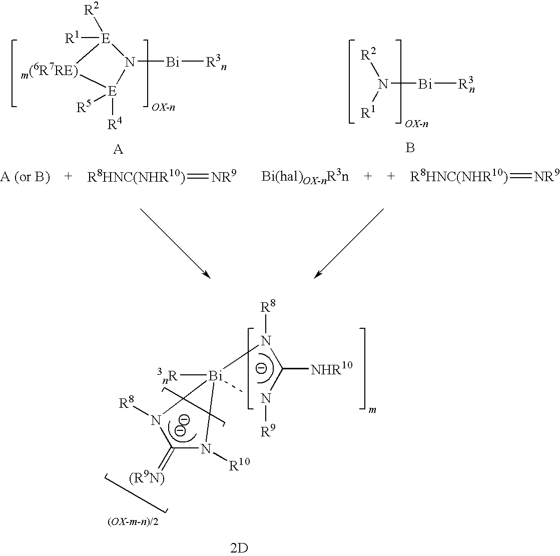

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX;

The bismuth ditelluroimidodiphosphinates are species within the broad scope of bismuth compounds of the invention having the following formulae:

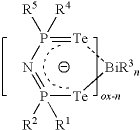

wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

Another class of bismuth compounds of the invention includes bismuth compounds of the formulae:

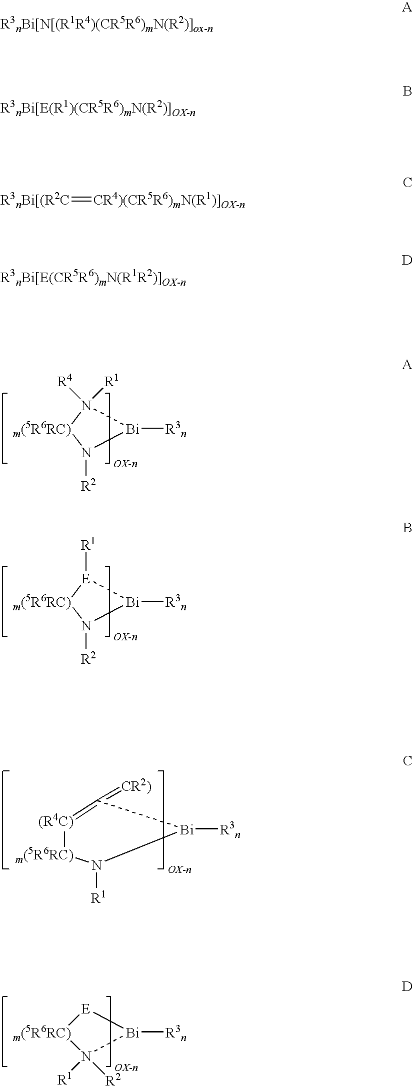

wherein:
each of R¹, R², R³, R⁴, R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n and m are each integers having a value of from 0 to OX;

### E is O or S.

A further class of bismuth compounds of the invention has the formula:

R³ₙBi(R¹)ₒₓ₋ₙ

wherein:
each of R¹ and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

Another class of bismuth compounds of the invention includes compounds of the formulae:

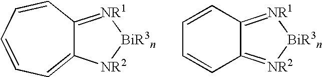

wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

A further class of bismuth compounds of the invention includes compounds of the formulae:

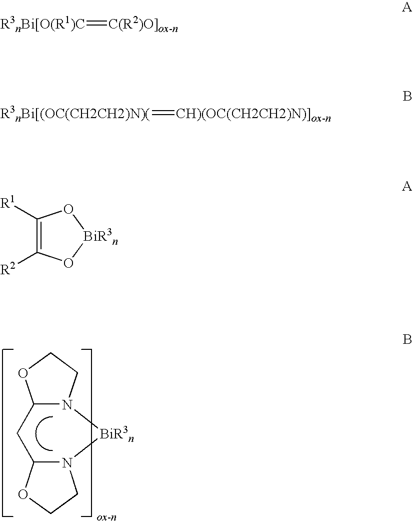

wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

The bismuth compounds of the formulae 2A, 2B, 2C and 2D,

R³ₙBi[(R⁸)NC[N(E(R¹R²)(E(R⁶R⁷))ₘE(R⁴R⁵))]N(R⁹)]_{OX-n} 2A

R³ₙBi[(R⁸)NC[N(R¹R²)]N(R⁹)]_{OX-n} 2B

R³ₙBi[(R⁸)NC(X)N(R⁹)]_{OX-n} 2C

R³ₙBi[(R⁸)NC(═NR⁹)N(R¹⁰)]_{(OX-m-n)/2}[(R⁸)NC(NHR¹⁰)N(R⁹)]ₘ 2D

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX;
may be readily synthesized by a synthesis process including the following reaction scheme:

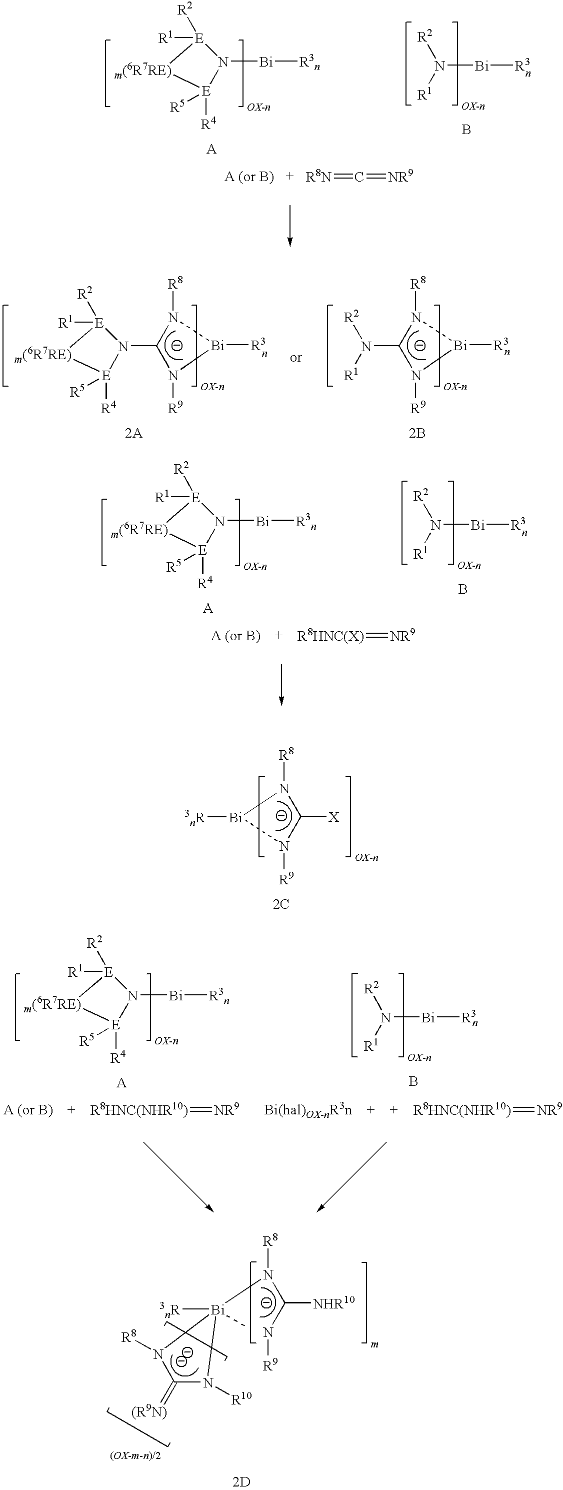

wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);

### E is C, Si or Ge;

n and m are integers having a value of from 0 to OX.

Other precursors of the present invention can be correspondingly readily synthesized without undue effort by those skilled in the art, based on the disclosure herein.

Bismuth precursors of the invention can be used to form amorphous bismuth-containing films, as well as crystalline bismuth-containing films, depending on the process conditions, deposition chamber configuration, substrate composition, etc. The determination of these process variables can readily be made by those of ordinary skill in the art, without undue experimentation, based on the disclosure herein and appropriate empirical effort involving varying process conditions and characterizing the resulting films, to establish a process condition envelope appropriate to a specific film-forming application.

Bismuth compounds of the invention may be used with appropriate co-reactants in a continuous deposition mode (CVD) or pulsed/atomic layer deposition mode (ALD) to deposit films of superior character. For oxides, preferred co-reactants include O₂ and N₂O for CVD, and more aggressive oxidizers for pulsed deposition, e.g., H₂O, ozone, and O₂ plasma. For metal-like films, reducing atmospheres are advantageously used.

For CVD modes of film formation, reducing agents such as H₂, and NH₃ are preferred, and plasmas of these co-reactants may be used in digital or ALD mode, wherein the co-reactants are separated from the precursor in a pulse train, utilizing general CVD and ALD techniques within the skill of the art, based on the disclosure herein. More aggressive reducing agents can also be used in a digital or ALD mode since co-reactants can be separated, preventing gas phase reactions. For ALD and conformal coverage in high aspect ratio structures, the precursor preferably exhibits self-limiting behavior in one type of atmosphere (e.g., inert or weakly reducing/oxidizing gas environments) and exhibits rapid decomposition to form a desired film in another type of atmosphere (e.g., plasma, strongly reducing/oxidizing environments).

Analogous metal cation precursors can be advantageously employed for CVD, while dissimilar species (i.e., different ligand species) can be employed in pulsed deposition.

The precursors of the invention can be utilized as low temperature deposition precursors with reducing co-reactants such as hydrogen, H₂/plasma, amines, imines, hydrazines, silanes, say' chalcogenides such as (Me₃Si)₂Te, germanes such as GeH₄, ammonia, alkanes, alkenes and alkynes. Liquid delivery formulations can be employed in which precursors that are liquids may be used in neat liquid form, or liquid or solid precursors may be employed in suitable solvents, including for example alkane solvents (e.g., hexane, heptane, octane, and pentane), aryl solvents (e.g., benzene or toluene), amines (e.g., triethylamine, tert-butylamine), imines and hydrazines. The utility of specific solvent compositions for particular Bi precursors may be readily empirically determined, to select an appropriate single component or multiple component solvent medium for the liquid delivery vaporization and transport of the specific bismuth precursor that is employed. In the case of solid precursors of the invention, a solid delivery system may be utilized, for example, using the ProE-Vap solid delivery and vaporizer unit (commercially available from ATMI, Inc., Danbury, Conn., USA).

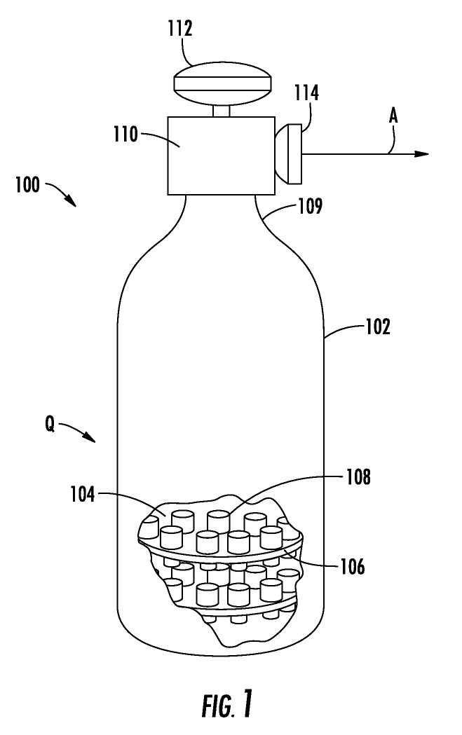

FIG. 1 is a schematic representation of a material storage and dispensing package 100 containing a bismuth precursor, according to one embodiment of the present invention.

The material storage and dispensing package 100 includes a vessel 102 that may for example be of generally cylindrical shape as illustrated, defining an interior volume 104 therein. In this specific embodiment, the precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly, for dispensing in use of the vessel.

The solid precursor can be coated on interior surfaces in the interior volume of the vessel, e.g., on the surfaces of the trays 106 and conduits 108. Such coating may be affected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein.

The vessel 102 has a neck portion 109 to which is joined the valve head assembly 110. The valve head assembly is equipped with a hand wheel 112 in the embodiment shown. The valve head assembly 110 includes a dispensing port 114, which may be configured for coupling to a fitting or connection element to join flow circuitry to the vessel. Such flow circuitry is schematically represented by arrow A in FIG. 1, and the flow circuitry may be coupled to a downstream ALD or chemical vapor deposition chamber (not shown in FIG. 1).

In use, the vessel 102 is heated, such input of heat being schematically shown by the reference arrow Q, so that solid precursor in the vessel is at least partially volatilized to provide precursor vapor. The precursor vapor is discharged from the vessel through the valve passages in the valve head assembly 110 when the hand wheel 112 is translated to an open valve position, whereupon vapor deriving from the precursor is dispensed into the flow circuitry schematically indicated by arrow A.

In lieu of solid delivery of the precursor, the precursor may be provided in a solvent medium, forming a solution or suspension. Such precursor-containing solvent composition then may be delivered by liquid delivery and flash vaporized to produce a precursor vapor. The precursor vapor is contacted with a substrate under deposition conditions, to deposit the metal on the substrate as a film thereon.

In one embodiment, the precursor is dissolved in an ionic liquid medium, from which precursor vapor is withdrawn from the ionic liquid solution under dispensing conditions.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

Supply vessels for precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular precursor of the invention.

The precursors of the invention thus may be employed to form precursor vapor for contacting with a substrate to deposit a bismuth-containing thin film thereon.

In a preferred aspect, the invention utilizes the precursors to conduct atomic layer deposition, yielding ALD films of superior conformality that are uniformly coated on the substrate with high step coverage and conformality even on high aspect ratio structures.

Accordingly, the precursors of the present invention enable a wide variety of microelectronic devices, e.g., semiconductor products, flat panel displays, etc., to be fabricated with bismuth-containing films of superior quality.

The invention in another aspect involves use of control agents to combat vapor phase pre-reaction of the precursors described herein, that otherwise causes uneven nucleation on the substrate, longer incubation times for deposition reactions, and lower quality product films. Such pre-reaction may for example be particularly problematic in applications involving chalcogenide films, related source materials (O, S, Se, Te, Ge, Sb, Bi, etc.), and/or manufacture of phase change memory and thermoelectric devices.

Pre-reaction may occur when the precursor reagents described herein are introduced to the deposition chamber, as in chemical vapor deposition, and may also occur in atomic layer deposition (ALD) processes, depending on the specific arrangement of ALD cycle steps and the specific reagents involved.

The invention therefore contemplates the use of control agents with the precursors described herein, whereby detrimental gas phase pre-reactions are suppressed, mitigated or eliminated, so that deposition reactions are induced/enhanced on the substrate surface, and films of superior character are efficiently formed.

The control agents that can be utilized with precursors of the invention for such purpose include agents selected from the group consisting of (i) heteroatom (O, N, S) organo Lewis base compounds, (ii) free radical inhibitors, and (iii) deuterium-containing reagents.

These agents can be utilized to lessen deleterious gas phase pre-reaction I'll precursors by various approaches, including:

(1) addition to the precursor composition of a pre-reaction suppressant comprising one or more heteroatom (O, N, S) organo Lewis base compounds such as 1,4-dioxane, thioxane, ethers, polyethers, triethylamine (TEA), triazine, diamines, N,N,N′,N′-tetramethylethylenediamine, N,N,N′-trimethylethylenediamine, amines, imines, and pyridine;

(2) addition to the precursor composition of a free radical inhibitor, such as butylated hydroxy toluene (BHT), hydroquinone, butylated hydro anisole (BHA), diphenylamine, ethyl vanillin, etc.;

(3) use of modified chalcogenide precursors, in which hydrogen substituents have been replaced with deuterium (D) substituents, to provide deuterated analogs for vapor phase deposition; and

(4) addition to the precursor composition of a deuterium source, to deuterate the precursor in situ.

The pre-reaction-combating agents described above (suppressants, free radical inhibitors, deuterium sources and/or deuterated precursors) can be introduced to any of the feed streams to the vapor deposition process in which the film is to be formed. For example, such pre-reaction-combating agents can be introduced to one or more of precursor feed stream(s), inert carrier gas stream(s) to which chalcogenide precursor(s) or other reagents are subsequently added for flow to the deposition chamber, co-reactant feed stream(s) flowed to the deposition chamber, and/or any other stream(s) that is/are flowed to the deposition chamber and in which the pre-reaction-combating agent(s) is/are useful for reduction or elimination of premature reaction of the precursors that would otherwise occur in the absence of such agent(s).

The aforementioned suppressants, free radical inhibitors and/or deuterium source reagents in specific embodiments are co-injected with the precursor(s), e.g., metal source reagent(s), to effect at least partial reduction of pre-reaction involving the precursor(s) and reagent(s).

The pre-reaction-combatting agent can alternatively be added directed to the deposition locus, e.g., the deposition chamber to which the precursor vapor is introduced for contacting with the substrate to deposit the film thereon, to suppress deleterious vapor phase pre-reaction involving the precursor(s) and/or other reagents.

As another approach, in the broad practice of the present invention, the suppressant, free radical inhibitor and/or deuterium source can be added to a solution containing the precursor and/or another metal source reagent, and the resulting solution can be utilized for liquid delivery processing, in which the solution is flowed to a vaporizer to form a source vapor for contacting with the substrate to deposit the deposition species thereon.

Alternatively, if the precursor and/or another metal source reagent are not in an existing solution, the suppressant, free radical inhibitor and/or deuterium source can be added to form a mixture or a solution with the precursor and/or another metal source reagent, depending on the respective phases of the materials involved, and their compatibility/solubility.

As a still further approach, the suppressant, free radical inhibitor and/or deuterium source can be utilized for surface treatment of the substrate prior to contacting of the substrate with the precursor and/or other metal source reagent.

The invention therefore contemplates various vapor deposition compositions and processes for forming films on substrates, in which pre-reaction of the precursors is at least partially attenuated by one or more pre-reaction-combating agents selected from among heteroatom (O, N, S) organo Lewis base compounds, sometimes herein referred to as suppressor agents, free radical inhibitors, and/or deuterium source reagents. Use of previously synthesized deuterated precursors or organometal compounds is also contemplated, as an alternative to in situ deuteration with a deuterium source. By suppressing precursor prereaction with these approaches, product films of superior character can be efficiently formed.

The control agent can be used for combating pre-reaction of chalcogenide precursor in a process in which multiple feed streams are flowed to a deposition locus to form a film on a substrate, wherein at least one of the multiple feed streams includes a precursor susceptible to pre-reaction adversely affecting the film, in which the method involves introducing the control agent to at least one of such multiple feed streams or supplied materials therefor, or to the deposition locus.

The pre-reaction combating reagent alternatively can be introduced to passivate the surface of a growing chalcogenide film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.), thereby carrying out passivation/retardation followed by reactivation steps, e.g., as an alternating repetitive sequence. Such sequence of passivation/retardation followed by reactivation can be carried out for as many repetitive cycles as desired, in ALD or ALD-like processes. The steps may be carried out for the entire deposition operation, or during some initial, intermediate or final portion thereof.

The invention therefore contemplates precursor compositions including the precursor and the pre-reaction-combating reagent. Within the categories of pre-reaction-combating reagents previously described, viz., (i) heteroatom (O, N, S) organo Lewis base compounds, (ii) free radical inhibitors, and (iii) deuterium-containing reagents, suitable pre-reaction-combating reagents for specific applications may be readily determined within the skill of the art, based on the disclosure herein.

Heteroatom (O, N, S) organo Lewis base compounds may be of varied type, e.g., containing an oxo (—O—) moiety, a nitrogen ring atom or pendant amino or amide substituent, a sulfur ring atom or pendant sulfide, sulfonate or thio group, as effective to at least partially lessen pre-reaction of the precursor and other organo metal reagents in the process system. Illustrative examples of heteroatom (O, N, S) organo Lewis base compounds having utility in specific applications of the invention include, without limitation, 1,4-dioxane, thioxane, ethers, polyethers, triethylamine, triazine, diamines, N,N,N′,N′-tetramethylethylenediamine, N,N,N′-trimethylethylenediamine, amines, imines, pyridine, and the like.

The heteroatom organo Lewis base compound in various specific embodiments of the invention may include a guanidinate compound, e.g., (Me₂N)₂C═NH.

One preferred class of heteroatom organo Lewis base compounds for such purpose includes R₃N, R₂NH, RNH₂, R₂N(CH₂)ₓNR₂, R₂NH(CH₂)ₓNR₂, R₂N(CR₂)ₓNR₂, and cyclic amines —N(CH₂)ₓ—, imidazole, thiophene, pyrrole, thiazole, urea, oxazine, pyran, furan, indole, triazole, triazine, thiazoline, oxazole, dithiane, trithiane, crown ethers, 1,4,7-triazacyclononane, 1,5,9-triazacyclododecane, cyclen, succinamide, and substituted derivatives of the foregoing, wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The heteroatom organo Lewis base compounds may be utilized in the precursor composition at any suitable concentration, as may be empirically determined by successive deposition runs in which the heteroatom organo Lewis base compound concentration is varied, and character of the resulting film is assessed, to determine an appropriate concentration. In various embodiments, the heteroatom organo Lewis base compound may be utilized in the concentration of 1-300% of the amount of precursor. Specific sub-ranges of concentration values within a range of 0.01-3 equivalents of the heteroatom organo Lewis base compound may be established for specific classes of precursors, without undue experimentation, based on the disclosure herein.

The pre-reaction-combating reagent may additionally or alternatively comprise free radical inhibitors that are effective to lessen the extent of pre-reaction between the precursor and another organo metal reagent. Such free radical inhibitors may be of any suitable type, and may for example include hindered phenols. Illustrative free radical inhibitors include, without limitation, free radical scavengers selected from the group consisting of: 2,6-ditert-butyl-4-methyl phenol, 2,2,6,6-tetramethyl-1-piperidinyloxy, 2,6-dimethylphenol, 2-tert-butyl-4-hydroxyanisole, 3-tert-butyl-4-hydroxyanisole, propyl ester 3,4,5-trihydroxy-benzoic acid, 2-(1,1-dimethylethyl)-1,4 benzenediol, diphenylpicrylhydrazyl, 4-tert-butylcatechol, N-methylaniline, 2,6-dimethylaniline, p-methoxydiphenylamine, diphenylamine, N,N′-diphenyl-p-phenylenediamine, p-hydroxydiphenylamine, phenol, octadecyl-3-(3,5-di-tert-butyl-4-hydroxyphenyl) propionate, tetrakis (methylene (3,5-di-tert-butyl-4-hydroxy-hydrocinnamate) methane, phenothiazines, alkylamidonoisoureas, thiodiethylene bis(3,5-di-tert-butyl-4-hydroxy-hydrocinnamate, 1,2-bis(3,5-di-tert-butyl-4-hydroxyhydrocinnamoyl) hydrazine, tris (2-methyl-4-hydroxy-5-tert-butylphenyl) butane, cyclic neopentanetetrayl bis(octadecyl phosphite), 4,4′-thiobis (6-tert-butyl-m-cresol, 2,2′-methylenebis (6-tert-butyl-p-cresol), oxalyl bis(benzylidenehydrazide) and mixtures thereof. Preferred free radical inhibitors include BHT, BHA, diphenylamine, ethyl vanillin, and the like.

Useful concentrations of the free radical inhibitor may be in a range of from 0.001 to about 0.10% by weight of the weight of the precursor, in various specific embodiments. More generally, any suitable amount of free radical inhibitor may be employed that is effective to combat the pre-reaction of the precursor in the delivery and deposition operations involved in the film formation process.

The deuterium source compounds afford another approach to suppressing pre-reaction of the chalcogenide precursor. Such deuterium source compounds may be of any suitable type, and may for example include deuterated pyridine, deuterated pyrimidine, deuterated indole, deuterated imidazole, deuterated amine and amide compounds, deuterated alkyl reagents, etc., as well as deuterated analogs of the precursors that would otherwise be used as containing hydrogen or protonic substituents.

Deuterides that may be useful in the general practice of invention as pre-reaction-combating reagents include, without limitation, germanium and antimony compounds of the formulae RₓGeD₄, and RₓSbD₃, wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The deuterium source reagent may be utilized at any suitable concentration that is effective to combat pre-reaction of the precursor. Illustrative deuterium source reagent concentrations in specific embodiments of the invention can be in a range of 0.01 to about 5% by weight, based on the weight of precursor.

Thus, a deuterium source compound may be added to one or more of the feed streams to the vapor deposition process, and/or one of the precursors or other feed stream components may be deuterated in the first instance.

The concentrations of the pre-reaction-combating agents utilized in the practice of the present invention to at least partially eliminate pre-reaction of the precursors can be widely varied in the general practice of the present invention, depending on the temperatures, pressures, flow rates and specific compositions involved. The above-described ranges of concentration of the pre-reaction-combating reagents of the invention therefore are to be appreciated as being of an illustrative character only, with applicable concentrations being readily determinable within the skill of the art, based on the disclosure herein.

The specific mode of introduction or addition of the pre-reaction-combating agent to one or more of the feed streams to the deposition process may correspondingly be varied, and may for example employ mass flow controllers, flow control valves, metering injectors, or other flow control or modulating components in the flow circuitry joining the source of the pre-reaction-combating agent with the streams being flowed to the deposition process during normal film-forming operation. The process system may additionally include analyzers, monitors, controllers, instrumentation, etc., as may be necessary or appropriate to a given implementation of the invention.

In lieu of introduction or addition of the pre-reaction-combating agent to one or more of the flow streams to the vapor deposition process, the pre-reaction-combating agent may be mixed with precursor in the first instance, as a starting reagent material for the process. For example, the pre-reaction-combating agent may be mixed in liquid solution with the precursor, for liquid delivery of the resulting precursor solution to a vaporizer employed to generate precursor vapor for contact with the substrate to deposit the film thereon.

As mentioned, the pre-reaction-combating agent may be added to the deposition locus to provide active gas-phase suppression of pre-reaction of the precursor vapor(s) that would otherwise be susceptible to such deleterious interaction.

As a still further alternative, the pre-reaction-combating agent may be used as a preliminary surface treatment following which the precursor and co-reactants (e.g., H₂, NH₃, plasma, H₂O, hydrogen sulfide, hydrogen selenide, diorganotellurides, diorganosulfides, diorganoselenides, etc.) are delivered to the substrate surface to effect deposition on such surface. For such purpose, the pre-reaction-combating agent may be introduced into one of more of the flow lines to the deposition process and flow to the substrate in the deposition process chamber, prior to initiation of flow of any precursors. After the requisite period of contacting of the substrate with such pre-reaction-combating agent has been completed, the flow of the pre-reaction-combating agent can be terminated, and normal feeding of flow streams to the deposition chamber can be initiated.

It will be apparent from the foregoing description that the pre-reaction-combating agent may be introduced in any of a wide variety of ways to effect diminution of the pre-reaction of the precursor in the deposition system.

In one embodiment of the invention, a vapor phase deposition system is contemplated, comprising:

a vapor deposition chamber adapted to hold at least one substrate for deposition of a film thereon;

chemical reagent supply vessels containing reagents for forming the film;

first flow circuitry arranged to deliver said reagents from said chemical reagent supply vessels to the vapor deposition chamber;

a pre-reaction-combating agent supply vessel containing a pre-reaction-combating agent;

second flow circuitry arranged to deliver the pre-reaction-combating agent from the pre-reaction-combating agent supply vessel to the first flow circuitry, to said chemical reagent supply vessels and/or to the vapor deposition chamber.

The pre-reaction-combating reagents may be employed in the broad practice of the present invention to produce improved films for the manufacture of semiconductor products. In general, the pre-reaction-combating reagents described herein may be utilized in various combinations in specific applications, to suppress or eliminate pre-reaction of the precursor and provide superior nucleation and final film properties.

The features and advantages of the invention are more fully shown by the following illustrative examples, which are not intended to be limitingly construed, as regards the scope and applicability of the present invention.

### Example 1

### The Synthesis and Characterization of Bi(Me-amd)₃

To a 250 mL Schlenk flask charged with 3.02 g PrⁱNCNPrⁱ (24 mmol) and 100 mL THF, 15 mL 1.6M MeLi (24 mmol) in hexane was added slowly at 0° C. (ice bath). The mixture was warmed up to room temperature and stirred overnight. 2.52 g BiCl₃ (7.99 mmol) was added slowly to the in-situ made PrⁱNC(Me)NPrⁱLi via an addition tube, at 0° C. (ice bath). The solution turned yellow immediately and was warmed up to room temperature and stirred overnight. All the volatiles were vacuumed and the residual was extracted with 50 mL pentane. After the filtration, all the volatiles were vacuumed again from the clear yellow filtrate and yielded 3.2 g crude Bi(Me-amd)₃ (5.06 mmol, 63% yield). The structure was consistent with the formula Bi(Me-amd)₃:

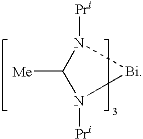

Data for Bi[PrⁱNC(Me)NPrⁱ]₃: ¹H NMR (benzene-d₆, 21° C.): δ 1.61 (d, 36H, (CH₃)₂CH—), 1.72 (s, 9H, CH₃C—), 4.60 (sept, 6H, (CH₃)₂CH—). ¹³C {¹H} NMR (benzene-d₆, 21° C.): δ 18.13 (CH₃C—), 25.92 ((CH₃)₂CH—), 47.39 ((CH₃)₂CH—); 164.95 (CH₃C—). Anal. Calcd for BiN₆C₂₄H₅₁: C, 45.56%; H, 8.12%; N, 13.28%; Found: C, 45.39%; H, 8.16%; N, 13.17%.

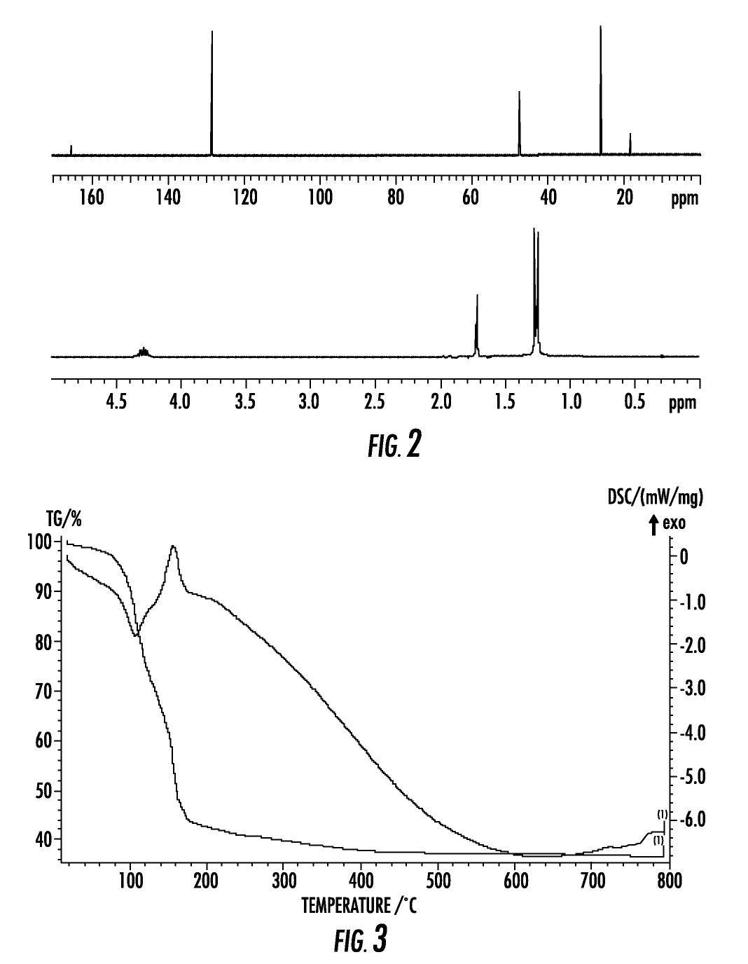

FIG. 2 is an nmr spectrum for the product Bi(Me-amd)₃.

FIG. 3 is an STA plot for the product Bi(Me-amd)₃ (8.76 mg sample with T50 at 162° C. and 36.5% mass residual).

### Example 2

### The Synthesis and Characterization of Bi(NBTMS)₃

To a 250 mL Schlenk flask charged with 7.93 g LiN(Bu^{t})(SiMe₃) (52 mmol) and 5.51 g BiCl₃ (17 mmol), 200 mL THF was added slowly at 0° C. (ice bath). The solution turned yellow immediately and was warmed up to room temperature and stirred overnight. All the volatiles were vacuumed and the residual was extracted with 50 mL pentane. After filtration, all the volatiles were vacuumed again from the clear yellow filtrate yielding 8.6 g crude Bi[N(Bu^{t})(SiMe₃)]₃ (13 3 mmol, 79% yield) The structure was consistent with the formula Bi[N(Bu^{t})(SiMe₃)]₃:

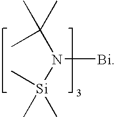

Data for Bi[N(Bu^{t})(SiMe₃)]₃: ¹H NMR (benzene-d₆, 21° C.): δ 0.39 (d, 27H, (CH₃)₂Si—), 1.58 (s, 27H, (CH₃)C—), ¹³C {¹H} NMR (benzene-d₆, 21° C.): δ 6.85 ((CH₃)₂Si—), 37.75 ((CH₃)C—), 59.5 ((CH₃)C—). Anal. Calcd for BiN₃C₂₁H₅₄Si₃: C, 39.29%; H, 8.48%; N, 6.55%. Found: C, 39.21%; H, 8.46%; N, 6.49%

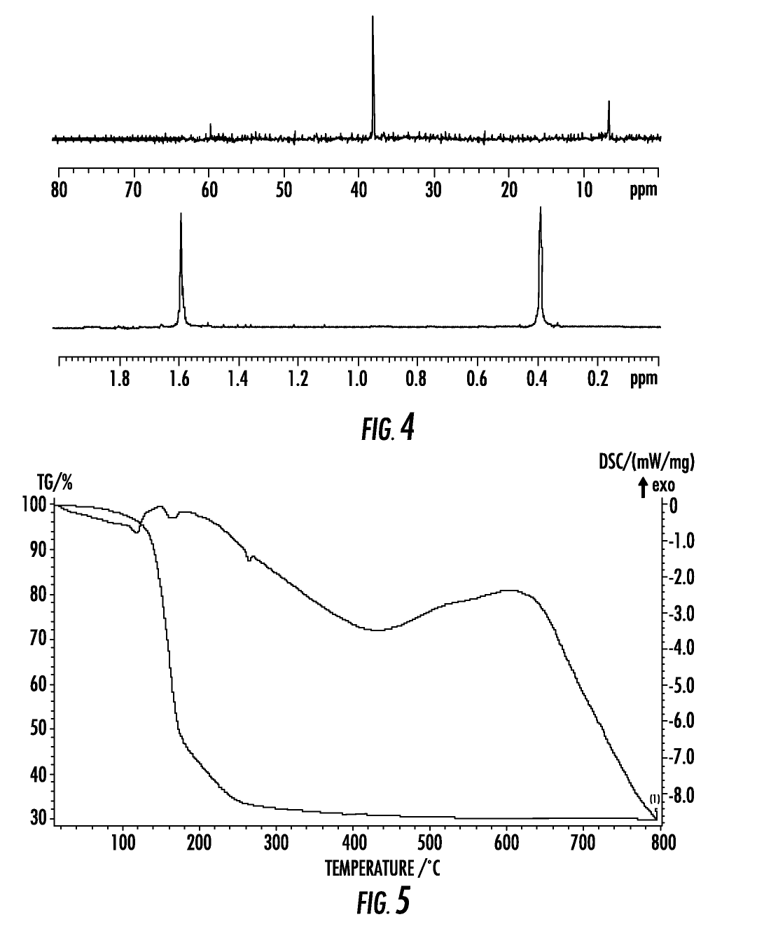

FIG. 4 is an nmr spectrum for the product Bi[N(Bu^{t})(SiMe₃)]₃.

FIG. 5 is an STA plot for the product Bi[N(Bu^{t})(SiMe₃)] (7.22 mg sample with T50 at 173° C. and 29.6% mass residual).

While the invention has been has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1. A bismuth precursor selected from among:
(I) bismuth compounds of the formula: 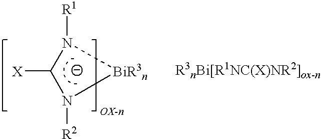
wherein:
X is selected from among H, C₁-C₆ alkyl, C₃-C₈ cycloalkyl, C₁-C₆ alkoxy, C₆-C₁₄ aryl, C₁-C₆ fluoroalkyl, C₃-C₁₈ alkylsilyl, silyl, amide, aminoalkyl, alkoxyalkyl, aryloxyalkyl, imidoalkyl, acetylalkyl and SiR₃ wherein each R is independently selected from branched and unbranched C₁-C₆ hydrocarbyl, e.g., alkyl;
each R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, amide, aminoalkyl, alkoxyalkyl, aryloxyalkyl, imidoalkyl, C₁-C₆ fluoroalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(II) bismuth compounds of the formula: 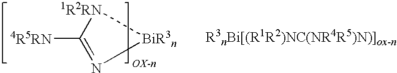
wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(III) bismuth compounds of the formula: 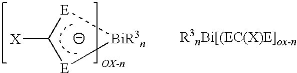
wherein:
E is either O or S;
X is selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
each R³ is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(IV) bismuth compounds of the formulae: 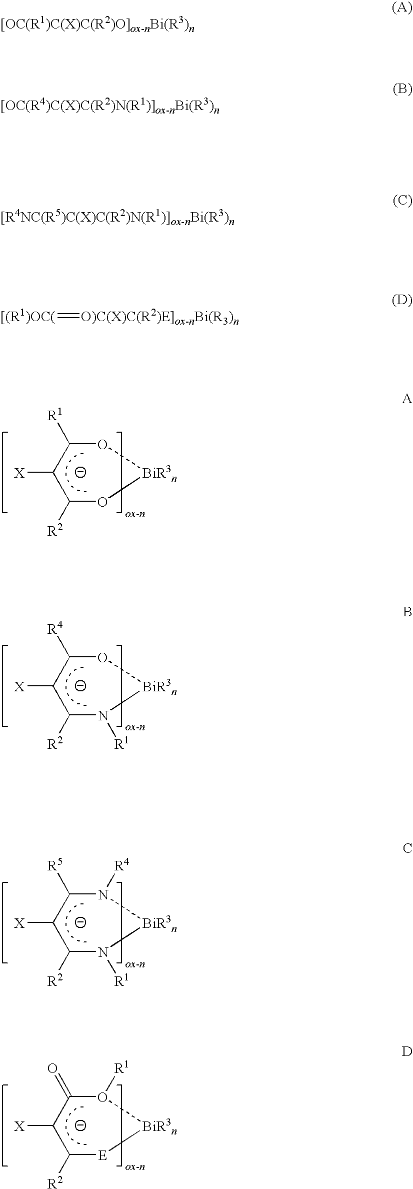
wherein:
X is selected from among C₁-C₆ alkyl, C₁-C₆ alkoxy, C₆-C₁₀ aryl, C₃-C₆ alkylsilyl, aminoalkyl, alkoxyalkyl, aryloxyalkyl, hydrogen, and acetylalkyl;
each R¹, R², R³, R⁴ and R⁵ may be the same as or different from the others, and each is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is oxygen or sulfur;
n is an integer having a value of from 0 to OX;
(V) bismuth compounds of the formulae: 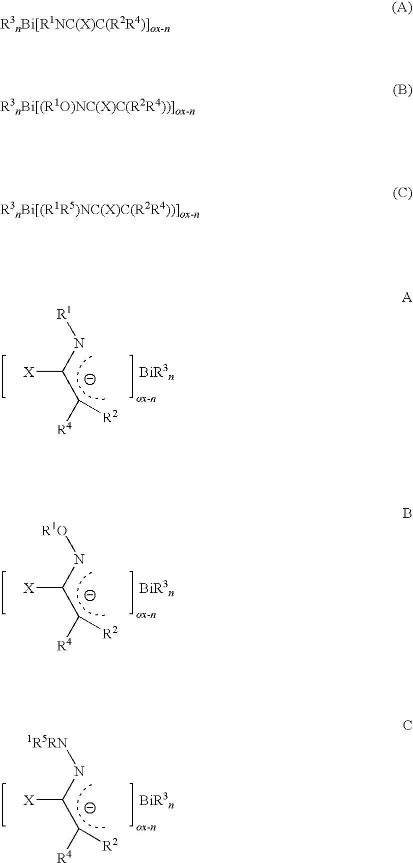
wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each of R¹, R², R³, R⁴ and R⁵ may be the same as or different from the others and is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
each R³ is independently selected from among C₁-C₆ alkyl, C₁-C₆ alkoxy, C₆-C₁₀ aryl, silyl, C₃-C₆ alkylsilyl, amide, aminoalkyl, alkoxyalkyl, aryloxyalkyl, imidoalkyl, hydrogen and acetylalkyl;
OX is the oxidation state of Bi (typically +3 or +5);
n is an integer having a value of from 0 to OX;
(VI) bismuth compounds of the formula: 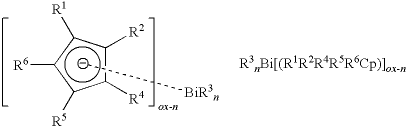
wherein:
Cp is cyclopentadienyl;
each of R¹, R², R³, R⁴, R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(VII) bismuth compounds of the formulae: 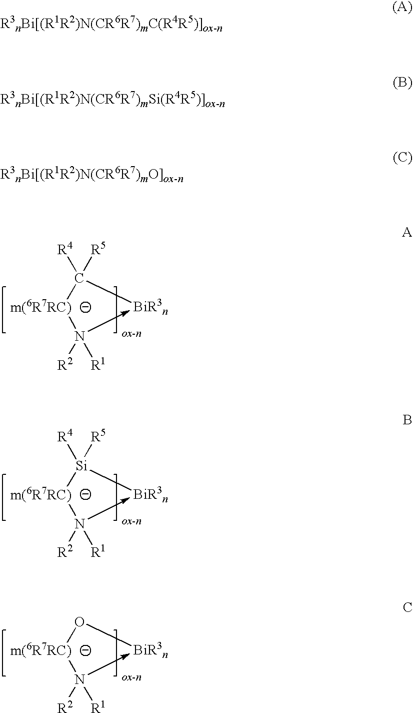
wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(VIII) bismuth compounds of the formulae: 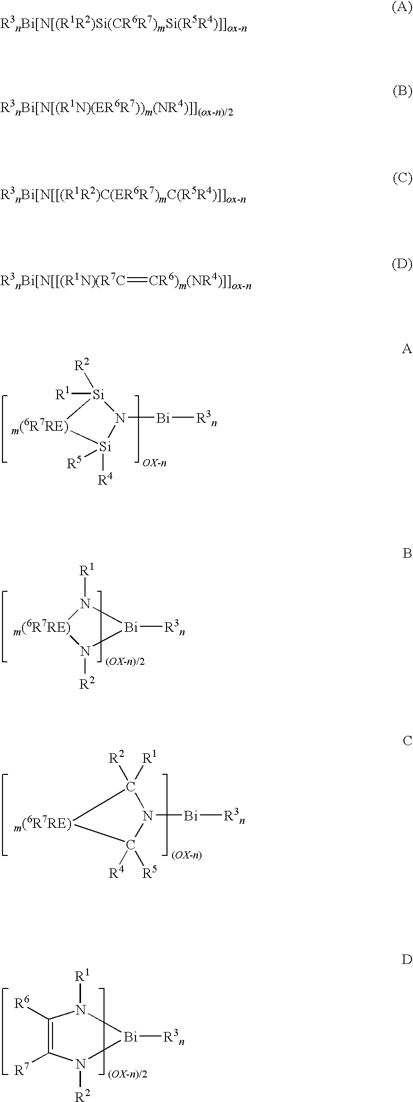
wherein:
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is C, Si or Ge;
n is an integer having a value of from 0 to OX;
(IX) bismuth compounds of the formulae: 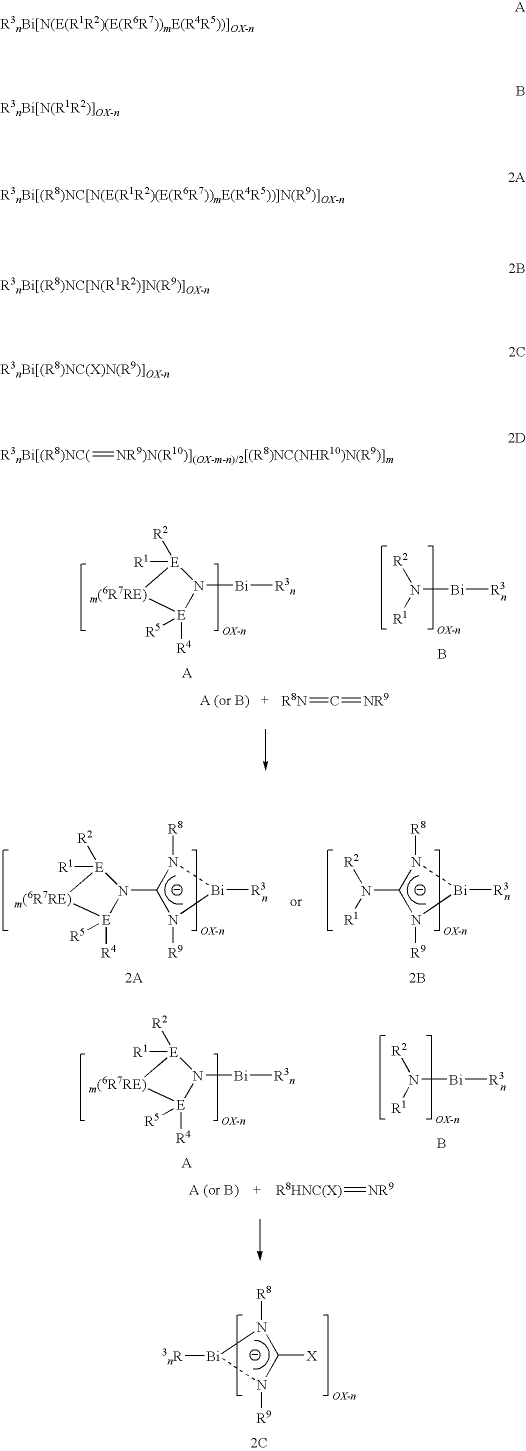 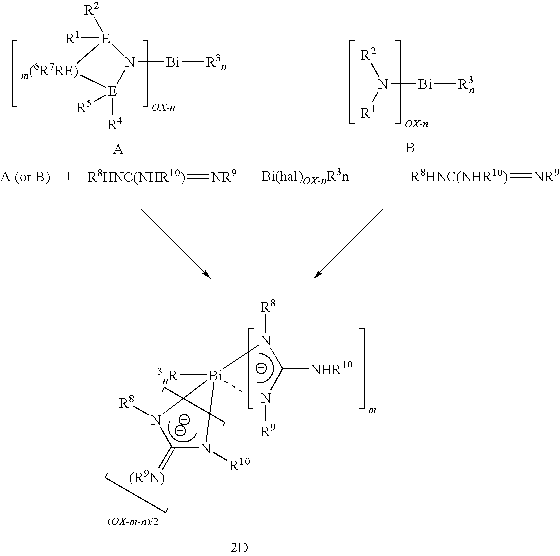
wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is C, Si or Ge;
n and m are integers having a value of from 0 to OX;
(X) bismuth compounds of the formula: 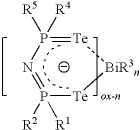
wherein:
each of R¹, R², R³, R⁴ and R⁵ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(XI) bismuth compounds of the formula: 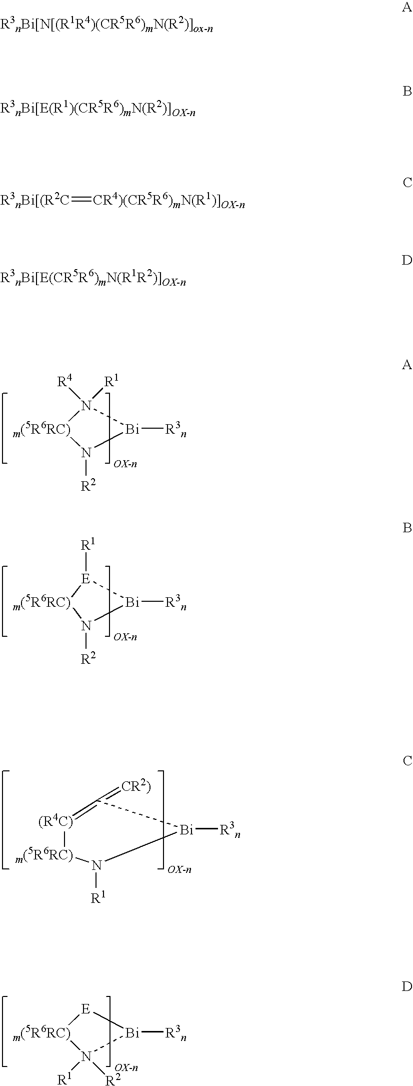
wherein:
each of R¹, R², R³, R⁴ R⁵ and R⁶ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n and m are each integers having a value of from 0 to OX;
E is O or S.
(XII) bismuth compounds of the formula:
R³ₙBi(R¹)ₒₓ₋ₙ
wherein:
each of R¹ and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX;
(XIII) bismuth compounds of the formula: 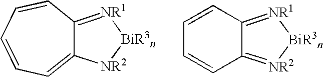
wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX; and
(XIV) bismuth compounds of the formula: 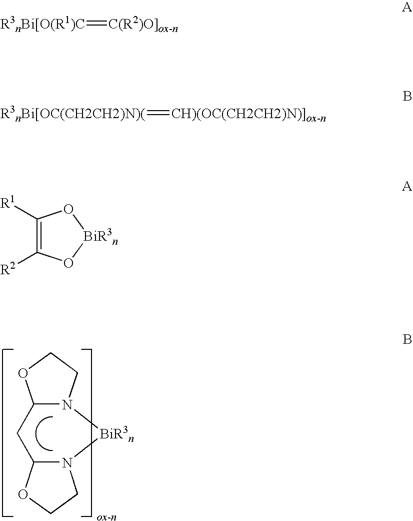
wherein:
each of R¹, R² and R³ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
n is an integer having a value of from 0 to OX.

2. A bismuth precursor according to claim 1, of formula (I).

3. A bismuth precursor according to claim 1, of formula (II).

4. A bismuth precursor according to claim 1, of formula (III).

5. A bismuth precursor according to claim 1, of formula (IV).

6. A bismuth precursor according to claim 1, of formula (V).

7. A bismuth precursor according to claim 1, of formula (VI).

8. A bismuth precursor according to claim 1, of formula (VII).

9. A bismuth precursor according to claim 1, of formula (VIII).

10. A bismuth precursor according to claim 1, of formula (IX).

11. A bismuth precursor according to claim 1, of formula (X).

12. A bismuth precursor according to claim 1, of formula (XI).

13. A bismuth precursor according to claim 1, of formula (XII).

14. A bismuth precursor according to claim 1, of formula (XIII).

15. A bismuth precursor according to claim 1, of formula (XV).

16. A method of forming a bismuth-containing film on a substrate, said method comprising volatilizing a bismuth precursor according to claim 1, to form a precursor vapor, and contacting said precursor vapor with a substrate to form said bismuth-containing film thereon, in a chemical vapor deposition process or an atomic layer deposition process.

17. A precursor composition comprising at least one bismuth precursor according to claim 1, and a solvent for the bismuth precursor(s).

18. A precursor vapor of a bismuth precursor according to claim 1

19. The method of claim 16, comprising at least one of: (i) liquid delivery of the bismuth precursor; (ii) solid delivery of the bismuth precursor; (iii) presence of an oxidant; (iv) presence of a co-reactant; and (v) presence of reducing conditions.

20. The method of claim 16, wherein said bismuth-containing film comprises a film selected from among GBT, Bi₂Te₃, Bi₄Ti₃O₁₂, SrBi₂Ta₂O₉, Bi—Ta—O, BiP and thermoelectric bismuth-containing films.

21. A precursor source package comprising a precursor storage and dispensing vessel containing a bismuth precursor according to claim 1.

22. A method of making a bismuth compound selected from among bismuth compounds of the formulae 2A, 2B, 2C and 2D,
R³ₙBi[(R⁸)NC[N(E(R¹R²)(E(R⁶R⁷))ₘE(R⁴R⁵))]N(R⁹)]_{OX-n} 2A
R³ₙBi[(R⁸)NC[N(R¹R²)]N(R⁹)]_{OX-n} 2B
R³ₙBi[(R⁸)NC(X)N(R⁹)]_{OX-n} 2C
R³ₙBi[(R⁸)NC(═NR⁹)N(R¹⁰)]_{(OX-m-n)/2}[(R⁸)NC(NHR¹⁰)N(R⁹]ₘ 2D
wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶ and R⁷ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is C, Si or Ge;
n and m are integers having a value of from 0 to OX;
said method comprising synthesizing said bismuth compound by a synthesis process including the following reaction scheme: 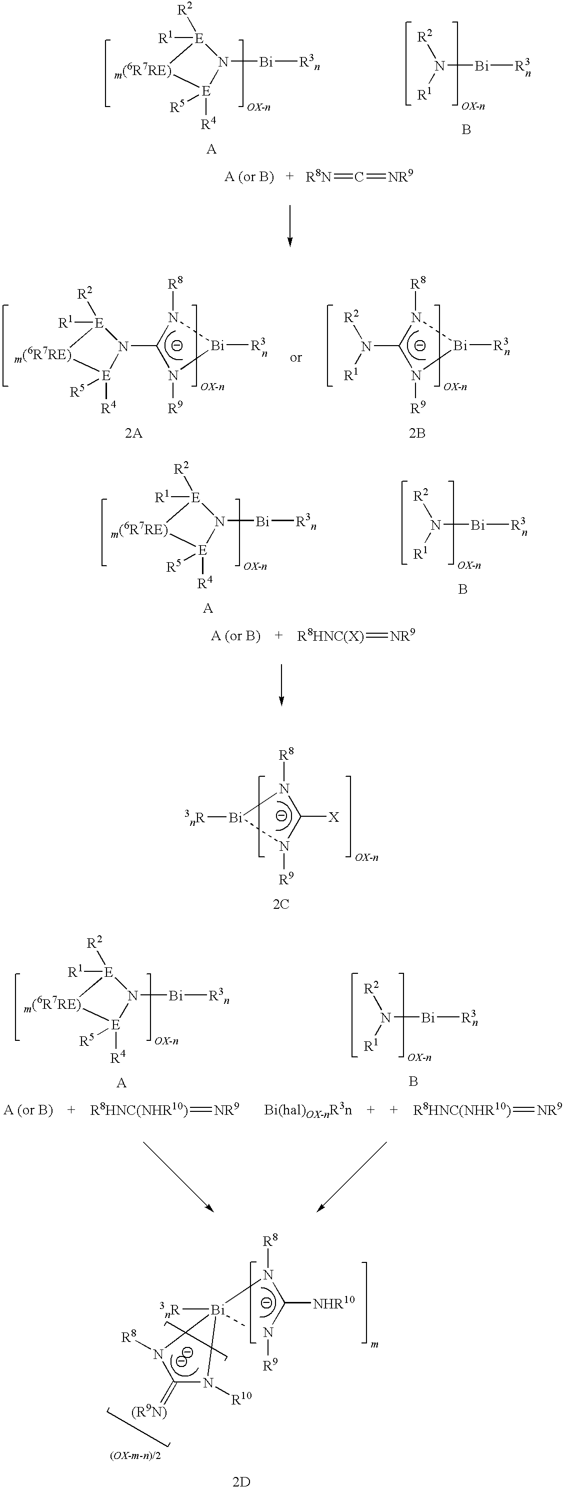
wherein:
X is selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R¹, R², R³, R⁴, R⁵, R⁶, R⁷, R⁸, R⁹ and R¹⁰ may be the same as or different from the others, and is independently selected from among H, C₁-C₆ alkyl, C₃-C₈ cycloalkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
R³ₙ may be the combination selected from among H, C₁-C₆ alkyl, C₃-C₈ cycloalkyl, C₁-C₆ alkoxy, C₆-C₁₄ aryl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of Bi (typically +3 or +5);
E is C, Si or Ge;
n and m are integers having a value of from 0 to OX.

23. A method of combating pre-reaction of a bismuth precursor according to claim 1 in a vapor deposition process for forming a film on a substrate, wherein the precursor is susceptible to pre-reaction adversely affecting the film, said method comprising introducing to said process a pre-reaction-combating agent selected from the group consisting of (i) (O, N, S) organo Lewis base compounds, (ii) free radical inhibitors, and (iii) deuterium-containing reagents.

24. The method of claim 16, wherein said process is carried out in manufacturing of a phase change random access memory device.
